(19) United States
(12) Patent Application Publication
(10) Pub. No.: US 2008/0003804 A1
(43) Pub. Date: Jan. 3, 2008

(54) Method of providing solder bumps of mixed sizes on a substrate using solder transfer in two stages

(76) Inventors: Ravi Nalla, Chandler, AZ (US); Mengzhi Pang, Phoenix, AZ (US); Charavana Gurumurthy, Higley, AZ (US)

Correspondence Address: INTEL CORPORATION;c/o INTELLEVATE, LLC, P.O. BOX 52050, MINNEAPOLIS, MN, 55402, US

(21) Appl. No.: 11/478,754

(22) Filed: Jun. 29, 2006

(51) Int. Cl. H01L 21/44

(52) U.S. Cl. 438/613; 257/E23.021

(57) ABSTRACT

A method of providing solder bumps on electrode pads of a microelectronic substrate. The method includes: disposing starter solder portions onto respective ones of the electrode pads; performing a starter reflow comprising reflowing the starter solder portions to form starter solder bumps on respective ones of the electrode pads; disposing respective filler solder portions onto respective ones of the starter solder bumps; and performing a filler reflow comprising reflowing the filler solder portions on respective ones of the starter solder bumps to yield respective final solder bumps on the electrode pads.

### FIELD

Embodiments of the present invention relate generally to solder bump forming methods and solder bump forming apparatus for forming solder bumps on electrode pads.

### BACKGROUND

There are a number of solder bump forming methods according to the prior art. According to a plating method, metal is deposited on electrode pads of a microelectronic substrate through plating to form bumps. In another method typically referred to as a stencil printing method, solder paste, typically including flux, is printed onto electrode pads of a microelectronic substrate through a patterned stencil, and then, after stencil removal, the device is heated to melt the solder to form bumps therefrom. However, it has been observed that the stencil printing method is not suited for high density interconnection structures, typically leading to missing bump rates, bump voiding, and bump height variation, thus negatively affecting die attachment yields.

Different techniques have been introduced to address ever growing demands for pitch and solder resist openings (SRO) size reductions, such as pitches of about 150 microns and SRO sizes of about 80 microns. One such method involves the placement of micro balls or micro spheres of solder onto the electrode pads of a microelectronic substrate. According to an attachment mounting micro ball placement method, solder balls are sucked into a jig by vacuum suction and the solder balls then mounted onto flux-coated electrode pads of a microelectronic substrate. According to yet another method, solder balls are held onto an adhesive layer of a base sheet in a stencil, and transferred onto electrode pads of a substrate. Another micro ball placement method involves the use of a stencil mask. According to the latter methods, solder balls of a uniform size are dispensed onto a ball alignment plate or stencil mask including holes therein in registration with electrode pads of a microelectronic substrate. A squeegee brush is then used to disperse the balls and press them into the mask holes. The electrode pads include flux thereon, which allows the balls to adhere thereto. The stencil mask is removed after ball placement. The solder balls are then heated and melted to form bumps.

The prior art also teaches the coating of solder powder onto an adhesive layer of a base sheet on a thermal compression bonder in order to allow a transfer of the solder via reflow onto electrode pads of a substrate having mixed solder resist openings thereon.

The prior art poses problems however, among others where bumps are to be provided on a substrate having electrode pads and/or solder resist openings of differing sizes. The prior art, such as, for example, the attachment mounting method or the stencil mask method described above, typically results in solder bumps exhibiting significant bump height variations from bump to bump depending on the size of the electrode pad and/or solder resist opening used.

The prior art fails to provide a reliable method of providing solder bumps on electrode pads and/or solder resist openings of differing sizes on a microelectronic substrate.

### BRIEF DESCRIPTION OF THE DRAWINGS

FIG. 1 is a schematic cross-sectional view of a substrate adapted to be provided with solder bumps according to a method embodiment;

FIGS. 2 and 3 are schematic views showing a starter solder transfer head in the process of delivering a starter solder material onto the substrate of FIG. 1 according to a first method embodiment;

FIG. 4 is a schematic view showing the starter solder material of FIGS. 2 and 3 as undergoing a starter reflow according to one embodiment;

FIG. 5 is a schematic view showing the substrate of FIG. 1 as including starter solder bumps thereon according to one embodiment;

FIGS. 6 and 7 are schematic views showing a filler solder transfer head in the process of delivering filler solder portions onto the starter solder bumps of FIG. 5 according to one embodiment;

FIG. 8 is a schematic view showing the filler solder portions and the starter solder bumps of FIGS. 6 and 7 as undergoing reflow according to one embodiment;

FIG. 9 is a schematic view of a bumped substrate obtained by practicing a method embodiment;

FIG. 10 is a schematic view of a system including a bumped microelectronic substrate such as the one shown in FIG. 9.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a method of providing solder bumps onto a microelectronic substrate is disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements.

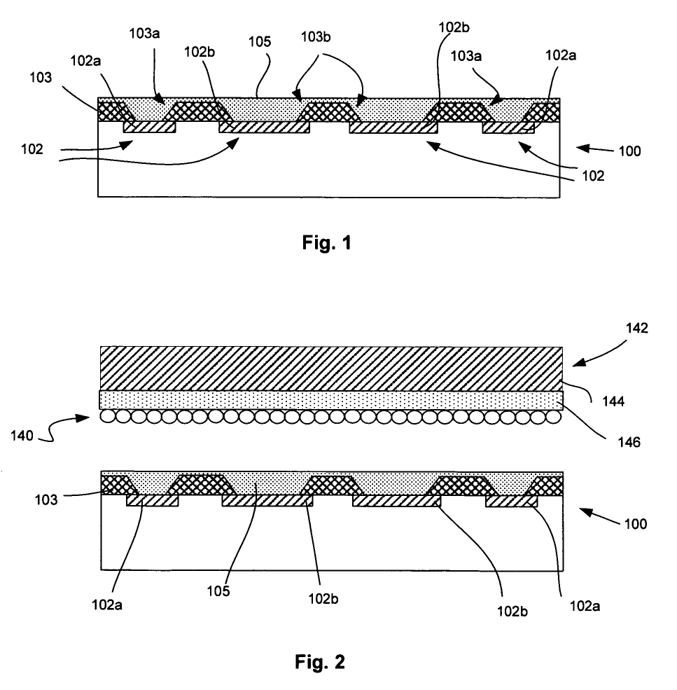

In one embodiment, a method of forming solder bumps on electrode pads of a microelectronic substrate is disclosed. By “electrode pads,” what is meant in the context of the instant description are bumping sites on a microelectronic substrate, such as under-bump metallization layers or “surface finish” layers, which allow the device to be electrically connected to other devices. Aspects of this and other embodiments will be discussed herein with respect to FIGS. 1-10, below. The figures, however, should not be taken to be limiting, as they are intended for the purpose of explanation and understanding.

Referring first to FIG. 1 by way of example, a method embodiment comprises providing a microelectronic substrate including electrode pads thereon. In the shown embodiment, the electrode pads include first and second electrode pads. By “microelectronic substrate,” what is meant in the context of the instant description is a substrate onto which microelectronic conductive patterns have been provided. The substrate may include either the substrate of a completed microelectronic device, or a substrate adapted to be further processed to form a microelectronic device, or a substrate, such as a printed wiring board, including conductive patterns adapted to provide interconnection between microelectronic components. For example the substrate can be an organic build-up substrate, a ceramic substrate, or a semiconductor substrate, such as a silicon substrate of a microelectronic die. As seen in FIG. 1, a method embodiment comprises providing a microelectronic substrate 100 including electrode pads 102 thereon. In the shown embodiments, the electrode pads 102 include first electrode pads 102a and second electrode pads 102b, wherein the second electrode pads 102b are larger than the first electrode pads 102a. The substrate 100 therefore exhibits a mixed pad size configuration. It is noted however, that embodiments are not limited to the use of a substrate having electrode pads of differing sizes, and includes within its scope a substrate having electrode pads of a substantially uniform size. Additionally, the pads may be set at differing or mixed pitches with respect to one another, or at a constant pitch, according to application needs. In the shown embodiment, pads 102 are set at mixed pitches with respect to one another. The electrode pads 102 may include any well known type of surface finish on the substrate, such as, for example, under bump metallization including layers of gold and nickel as would be within the knowledge of a person skilled in the art. According to one embodiment, the substrate may include a solder resist layer 103 thereon. The solder resist layer 103 (also called a “solder mask” or “stop-off”) is an insulating layer that is patterned with holes according to a pattern of the electrode pads. The solder resist may include a heat-resisting coating material applied to specific areas on the surface of a substrate, and is provided mainly as a protective film for the conductive patterns of the substrate. According to an embodiment, solder resist layer 103 may include a mixture of an epoxy resin and an acrylic resin, and may be coated onto the substrate in a well known manner. As shown, solder resist layer 103 may define first solder resist openings 103a therethrough placed in registration with corresponding ones of the electrode pads 102a, and second solder resist openings 103b therethrough placed in registration with corresponding ones of the electrode pads 102b. As shown, solder resist openings 103b are larger than solder resist openings 103a. The solder resist layer 103 in the shown embodiment therefore defines mixed solder resist openings therethrough, that is, solder resist openings of mixed sizes. It is noted that embodiments are not limited to the use of a substrate including a solder resist thereon, and include within their scope a processing of a substrate free of a solder resist layer. In the shown embodiment of FIG. 1, flux 105 is additionally shown as having been provided onto the electrode pads. The flux may include a flux having relatively high tackiness, and may be applied onto the pads in any well known manner. Preferably, as depicted in the embodiment of FIG. 1, the flux 105 is in the form of a flux layer extending above an upper limit of the solder resist layer 103 as shown. However, embodiments include within their scope the provision of flux 105 only in the solder resist openings below an upper limit of the solder resist layer 103.

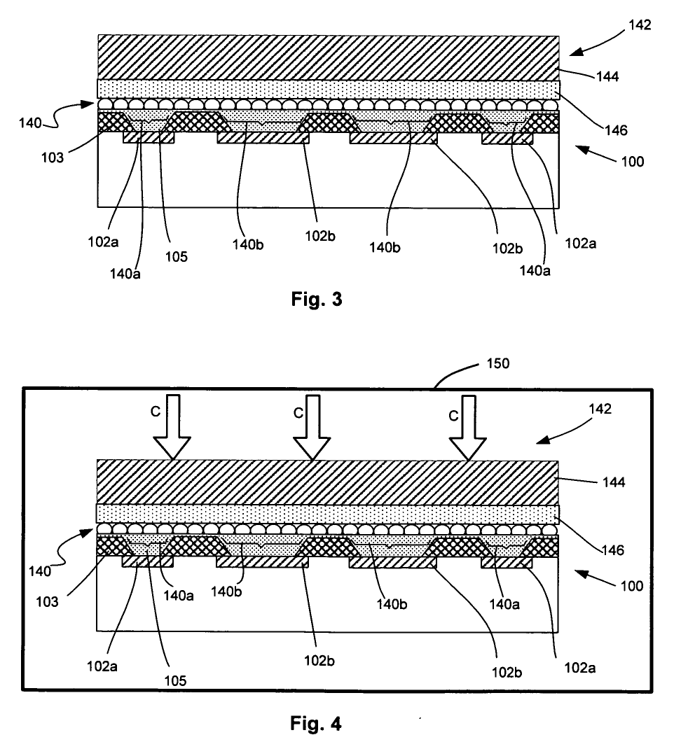

Referring next to FIGS. 2 and 3 by way of example, a method embodiment comprises disposing first starter solder portions onto respective ones of the first electrode pads and second starter solder portions onto respective ones of the second electrode pads, each of the second starter solder portions having a larger volume than each of the first starter solder portions. According to the shown embodiment of FIGS. 2 and 3, to provide the starter solder portions, a starter solder material 140, such as, for example, solder powder, may be attached onto a starter solder transfer head 142 including a base sheet 144 and an adhesive layer 146 provided onto the base sheet. Thus, in the shown embodiment of FIG. 2, the starter solder material 140 in the form of solder powder is depicted as having been coated onto the adhesive layer 146 of starter solder transfer head 142, the powder particles adhering to the adhesive layer 146. As seen in FIG. 3, disposing the first and second starter solder portions may also include, according to the shown embodiment, contacting the starter solder material 140 to the flux layer 105 of the substrate 100 by moving the solder transfer head 142 into position above the substrate. In this way, parts of the starter solder material 140 will be disposed on each of the first electrode pads 102a and parts of the starter solder material 140 may be disposed on each of the second electrode pads 102b. Each part of the starter solder material 140 disposed on a first electrode pad 102a will correspond to a first starter solder portion 140a, and each part of the starter solder material 140 disposed on a second electrode pad will correspond to a second starter solder portion 140b. As seen in FIG. 3, each second starter solder portion 140b has a larger volume than each first starter solder portion 140a. The latter is true in the shown embodiment because the second solder resist openings 103b are larger than the first solder resist openings 103a. The above notwithstanding, it is noted that embodiments are not limited to first and second starter solder portions that are parts of a coating of solder powder. Rather, embodiments include within their scope first and second starter solder portions of any form.

Referring now to FIG. 4 by way of example, a method embodiment further comprise performing a starter reflow, which comprises reflowing the first starter solder portions and the second starter solder portions to form, respectively, first starter solder bumps on respective ones of the first electrode pads and second starter solder bumps on respective ones of the second electrode pads. Thus, referring to the embodiment of FIG. 4, after contacting the starter solder material 140 to the substrate 100 by way of the flux layer 105 as shown in FIG. 3, the starter solder material 140 may be subjected to reflow, such as, for example, by way of thermal compression bonding. As shown in FIG. 4, the thermal compression bonding process applied to reflow the starter solder material 140 has been depicted schematically by way of arrows C suggesting the application of a compressive force onto the starter solder transfer head 142 to press the starter solder material 140, including first starter solder portions 140a and second starter solder portions 140b, onto the substrate 100. Thermal compression bonding in FIG. 4 has additionally been depicted by way of the positioning of the substrate 100 including the starter solder material 140 thereon in a reflow oven 150. In an alternative embodiment, the starter reflow of the first and second starter solder portions may comprise reflowing without the use of thermal compression bonding. The starter reflow may take place at reflow temperatures suitable for the starter solder material 140, as would be recognizable to one skilled in the art. According to an embodiment, reflow may take place at temperatures above about 220 degrees Centigrade. The 220 degrees Centigrade minimum reflow temperature would for example apply to solder balls comprising a SnAg or a SnAgCu alloy. The SnAg may comprise less than about 4% by weight Ag, while the SnAgCu may comprise less than about 1% by weight Cu and less than about 4% by weight Ag

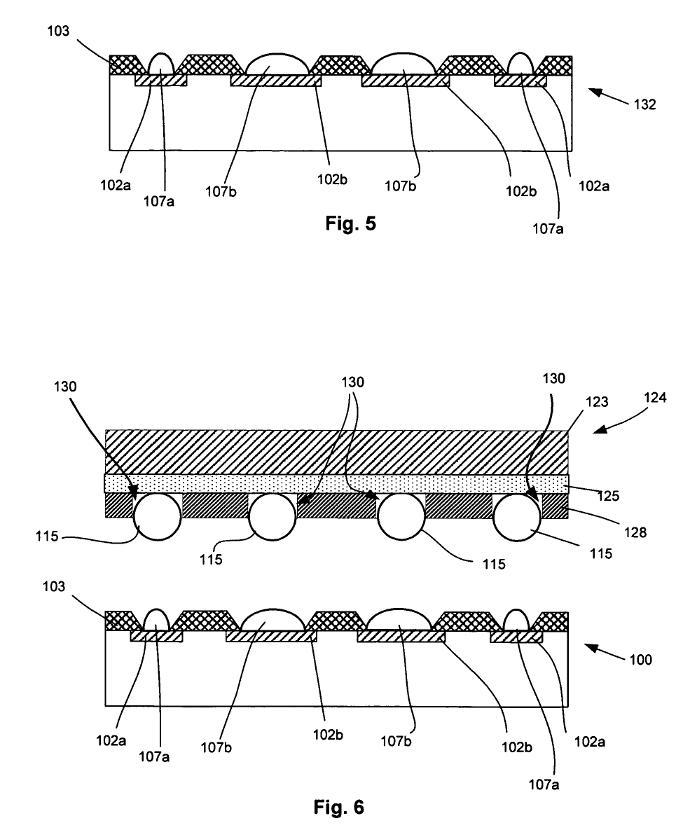

As seen in FIG. 5, the starter reflow of the starter solder material 140 including the first starter solder portions 140a and the second starter solder portions 140b results in a transfer of the starter solder material 140 from the base sheet 144 onto the electrode pads 102a and 102b, and more specifically in the formation of starter solder bumps 107a and 107b onto electrode pads 102a and 102b of substrate 100, yielding an intermediate solder-bumped substrate 132 as shown. During reflow in the case of an embodiment as depicted in FIG. 5 when the starter solder material 140 includes a coating of solder powder onto a solder transfer head such as solder transfer head 142, the starter reflow melts the solder powder existing in regions between the first starter solder portions 140a and second starter solder portions 140b such that this melted solder flows into one or more of the adjacent electrode pads. The adhesive may be selected such that, during starter reflow, it at least partially volatilizes. Optionally, after the starter reflow, any excess solder or flux may be removed by cleaning the active surface of the substrate 100 including the starter solder bumps 107a and 107b in a well known manner, such as by using water dispensed at an elevated pressure onto the substrate 100 after formation of the starter solder bumps. In the shown embodiment, the intermediate solder-bumped substrate 132 includes the plurality of electrode pads 102a and 102b, first starter solder bumps 107a and second starter solder bumps 107b on corresponding ones of the electrode pads 102a and 102b, bumps 107b being larger than bumps 107a. The intermediate solder bumped substrate 132 as shown further includes the solder resist layer 103 thereon, although, as noted previously, embodiments are not limited to the use of a substrate including a solder resist layer. As suggested in FIG. 5 to be discussed infra, after the starter reflow, the starter solder transfer head 142 may be retracted, and the base sheet 144 removed therefrom after solder transfer. The base sheet may preferably then be reused for further similar applications. According to a preferred embodiment, the base sheet is made of a material having a coefficient of thermal expansion which is similar to a coefficient of thermal expansion of the substrate material.

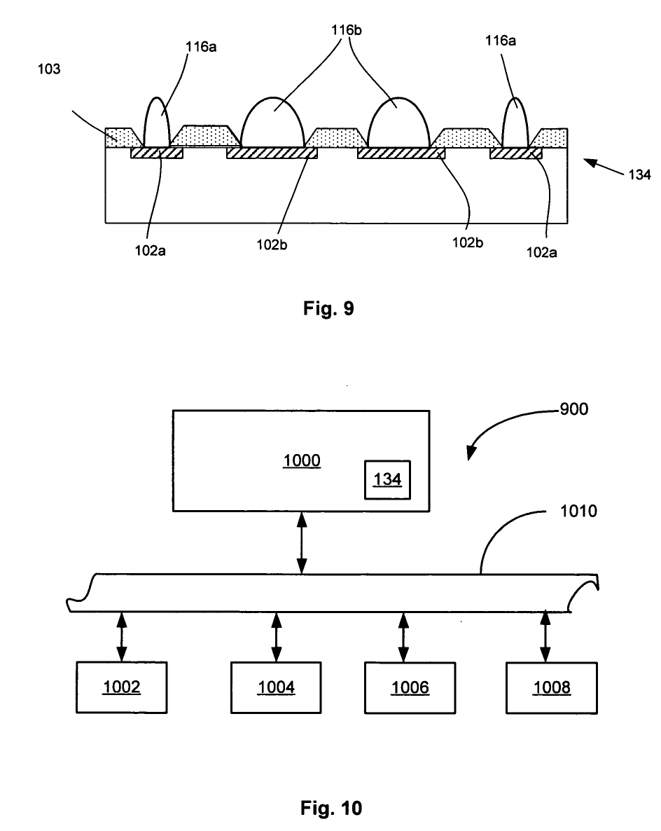

Preferably, an embodiment comprises selecting an amount of the starter solder material to achieve first final solder bumps and second final solder bumps having substantially identical bump heights, as will be explained in more detail in relation to FIG. 9. Thus, for example, according to an embodiment, a thickness of the solder powder to be provided onto the base sheet 142 may be empirically linked to a given resulting final solder bumps height on the substrate 100 for a given volume of each of the filler solder portions 115. In this way, a thickness of the solder powder coated onto the adhesive layer 146 may be chosen such that, after filler reflow as will be explained in more detail in relation to FIG. 8, final solder bumps 116a and 116b have substantially identical bump heights.

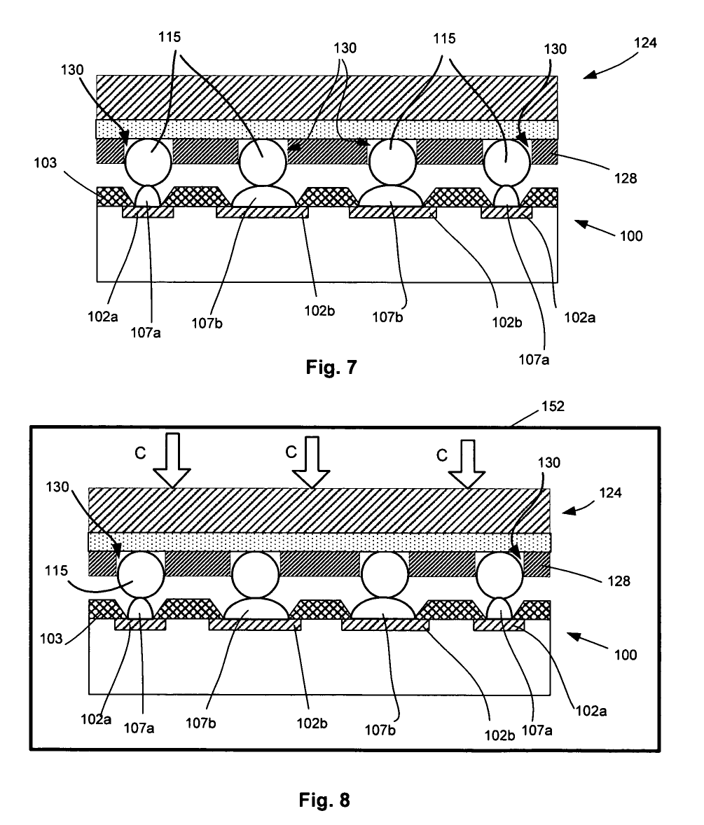

Referring now to FIGS. 6 and 7 by way of example, a method embodiment comprises disposing respective filler solder portions onto respective ones of the first starter solder bumps and second starter solder bumps. Thus, as seen in the embodiment of FIG. 6, filler solder portions in the form, for example, of solder balls 115, may be disposed on each of the starter solder bumps 140a and 140b. In the shown embodiment, there is a single solder portion or solder ball 115 for each starter solder bump 140a/140b. According to the shown embodiment of FIGS. 6 and 7, to provide the filler solder portions, solder balls may be attached onto a filler solder transfer head 124 including a base sheet 123 and an adhesive layer 125 provided onto the base sheet 123. Thus, in the shown embodiment of FIG. 6, the filler solder portions in the form of solder balls 115 are depicted as having been adhered onto an adhesive layer 125 of starter solder transfer head 124. According to one embodiment, as shown in FIGS. 6 and 7, in order to keep the solder balls 115 in position on the adhesive layer 125, a stencil layer 128 may be provided defining stencil openings 130 therein. According to one embodiment, the stencil layer 128 may comprise a dry film resist layer. As seen in FIGS. 6 and 7, the stencil openings 130 are provided in the stencil layer 128 in such a way as to exhibit a pattern corresponding to a pattern of the first electrode pads 102a and the second electrode pads 102b of the substrate 100. In other words, according to an embodiment, the stencil openings 130 may be provided in the stencil layer 128 such that, when and if the stencil layer 128 is disposed on the substrate 100, respective ones of the stencil openings 130 register with corresponding ones of the electrode pads 102a/102b on the substrate 100. In particular, referring now to FIG. 7, disposing the filler solder portions may also include, according to the shown embodiment, moving the topper solder transfer head 124 so as to contact respective ones of the solder balls 115 to corresponding ones of the first starter solder bumps 140a and the second starter solder bumps 140b. Because the stencil layer 128 has openings 130 which exhibit a pattern corresponding to a pattern of the electrode pads 102a and 102b, by bringing the solder balls 115 in contact with respective starter solder bumps 107a and 107b using the filler solder transfer head 124, each solder ball 115 may be disposed on a corresponding one of the first starter solder bumps 107a and the second starter solder bumps 107b. According to one embodiment (not shown), prior to attaching the topper solder portions, such as solder balls 115, to a topper solder transfer head, such as topper solder transfer head 124, the adhesive layer 125 may be coated with a layer of flux. As seen in FIGS. 6 and 7, according to one embodiment, the filler solder portions, which, in the shown embodiment, comprise solder balls 115, may be of substantially identical volumes with respect to one another. The above notwithstanding, it is noted that embodiments are not limited to filler solder portions in the form of solder balls. Rather, embodiments include within their scope filler solder portions of any form.

Referring now to FIG. 8 by way of example, a method embodiment further comprises performing a filler reflow, which comprises reflowing the filler solder portions on respective ones of the first starter solder bumps and second starter solder bumps to form respective first and second final solder bumps, the first final solder bumps being on the first electrode pads, and the second final solder bumps being on the second electrode pads. Thus, referring to the embodiment of FIG. 8, after contacting the respective filler solder portions or solder balls 115 to corresponding ones of the first starter solder bumps 107a and second starter solder bumps 107b, the combination of the solder balls 115 and starter solder bumps 107a/107b may be subjected to reflow, such as, for example through thermal compression bonding to transfer the solder balls. By “reflow,” what is meant in the context of the instant description is any process that at least partially leads to an elevation of the temperature of the solder above its liquidus temperature, and a subsequent cooling of the solder below its solidus temperature. As shown in FIG. 8, similar to the starter reflow shown in FIG. 4, the thermal compression bonding process applied to the filler reflow has been depicted schematically by way of arrows C suggesting the application of a compressive force onto the filler solder transfer head 124 to press the solder balls 115 to corresponding ones of the starter solder bumps 107a/107b. Thermal compression bonding in FIG. 8 has additionally been depicted by way of the positioning of the substrate 100 including the solder balls 115 and starter solder bumps 107a/107b thereon in a reflow oven 152. In an alternative embodiment, the filler reflow may comprise reflowing without the use of thermal compression bonding. The adhesive may be selected such that, during starter reflow, it at least partially volatilizes. Optionally, after the starter reflow, any excess solder or flux may be removed by cleaning the active surface of the substrate 100 including the final solder bumps 107a and 107b in a well known manner, such as by using water dispensed at an elevated pressure onto the substrate 100 after formation of the starter solder bumps. The filler reflow may take place at reflow temperatures suitable for the solder balls 115, as would be recognizable to one skilled in the art. According to an embodiment, reflow may take place at temperatures above about 220 degrees Centigrade. The 220 degrees Centigrade minimum reflow temperature would for example apply to solder balls comprising a SnAg or a SnAgCu alloy. The SnAg may comprise less than about 4% by weight Ag, while the SnAgCu may comprise less than about 1% by weight Cu and less than about 4% by weight Ag.

As seen in FIG. 9, the filler reflow of the filler solder portions and first and second starter solder bumps 107a and 107b results in a transfer of the solder balls 115 from the base sheet 124 onto the electrode pads 102a and 102b, and, more specifically, in the formation of final solder bumps 116a and 116b onto electrode pads 102a and 102b of substrate 100, yielding a final solder-bumped substrate 134 as shown. During reflow in the case of an embodiment as depicted in FIG. 9, when the filler solder portions comprise solder balls 115 on a solder transfer head such as solder transfer head 124, the filler reflow melts the solder balls 115 and the starter solder bumps 107a and 107b to form final solder bumps 116a and 116b therefrom. In the shown embodiment, the final solder-bumped substrate 134 includes the plurality of electrode pads 102a and 102b, first final solder bumps 116a and second final solder bumps 116b on corresponding ones of the electrode pads 102a and 102b, bumps 116b being larger than bumps 116a, and bumps 116a and 116b having substantially identical heights. Solder bumps have “substantially identical heights” as described therein where their respective heights are within bump height variation tolerances according to application needs. Thus, a given application may specify a requirement for substrates having bump heights of 30 microns with tolerances of +/−15 microns. In such a case, solder bumps as described herein would have “substantially identical heights” where their heights would range from between 15 microns up to 45 microns. In the alternative, if the tolerances specified were +/−5 microns, then, solder bumps as described herein would have “substantially identical heights” where their heights would range from between 25 microns and 35 microns. The final solder bumped substrate 132 as shown further includes the solder resist layer 103 thereon, although, as noted previously, embodiments are not limited to the use of a substrate including a solder resist layer. As suggested in FIG. 9 to be discussed infra, after the filler reflow, the filler solder transfer head 124 may be retracted, and the base sheet 128 removed therefrom after solder transfer. The base sheet may then be reused for further similar applications. Similar to the base sheet 144 of FIGS. 2-4, base sheet 128 may, according to a preferred embodiment, be made of material that has a coefficient of thermal expansion similar to a coefficient of thermal expansion of the underlying substrate 100.

Advantageously, method embodiments allow for a more precise solder bump volume and height control by virtue of allowing a placement and reflow of solder portions onto the electrode pads of a substrate using a two stage solder placement process, where the amount of the solder portions at each stage may be monitored to achieve a desired bump height on each of the electrode pads. Method embodiments are among other things suited for substrates presenting electrode pads/solder resist openings having mixed sizes, by allowing a tailoring of delivered solder portions onto each electrode pad with a desired bump height in mind. The more precise bump volume and height control according to an embodiment allows a more reliable formation of solder joints during chip attachment, and thus results in a significantly lower amount of solder voids, missing bumps and resulting electromigration issues as compared with the prior art.

Referring to FIG. 10, there is illustrated one of many possible systems 900 in which embodiments of the present invention may be used. In one embodiment, the electronic assembly 1000 may include a microelectronic package 134 including a solder-bumped substrate, such as substrate 134 of FIG. 9. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 10, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A method of providing solder bumps on electrode pads of a microelectronic substrate comprising:
disposing starter solder portions onto respective ones of the electrode pads;
performing a starter reflow comprising reflowing the starter solder portions to form starter solder bumps on respective ones of the electrode pads;
disposing respective filler solder portions onto respective ones of the starter solder bumps; and
performing a filler reflow comprising reflowing the filler solder portions on respective ones of the starter solder bumps to yield respective final solder bumps on the electrode pads.

2. The method of claim 1, wherein:
the electrode pads comprise first electrode pads and second electrode pads,
the starter solder portions comprise first starter solder portions and second starter portions, each of the second starter solder portions having a larger volume than each of the first starter solder portions;
the starter solder bumps comprise first starter solder bumps and second starter solder bumps;
the final solder bumps comprise first final solder bumps and second final solder bumps;
disposing starter solder portions comprises disposing the first starter solder portions onto respective ones of the first electrode pads, and the second starter solder portions onto respective ones of the second electrode pads;
performing a starter reflow comprises reflowing the first starter solder portions and the second starter solder portions to form, respectively, the first starter solder bumps on respective ones of the first electrode pads, and the second starter solder bumps on respective ones of the second electrode pads;
disposing respective filler solder portions comprise disposing the respective filler solder portions onto respective ones of the first starter solder bumps and the second starter solder bumps; and
performing a filler reflow comprises reflowing the filler solder portions on respective ones of the first starter solder bumps and the second starter solder bumps to respectively yield the first final solder bumps and the second final solder bumps, the first final solder bumps being on the first electrode pads, and the second final solder bumps being on the second electrode pads.

3. The method of claim 2, wherein the second electrode pads are larger than the first electrode pads.

4. The method of claim 2, wherein the first final solder bumps and the second final solder bumps have substantially identical heights.

5. The method of claim 2, wherein the first starter solder bumps and the second starter solder bumps have substantially identical heights.

6. The method of claim 1, wherein the filler solder portions are of substantially identical volumes with respect to one another.

7. The method of claim 2, wherein the first starter solder portions and the second starter solder portions comprise solder powder.

8. The method of claim 1, wherein the each of the filler solder portions comprises a solder ball.

9. The method of claim 2, wherein:
disposing a first starter solder portion and a second starter solder portion comprises:
attaching a starter solder material onto a starter solder transfer head;
after attaching, contacting the starter solder material to the substrate such that parts of the starter solder material corresponding to the first starter solder portions are disposed on the first electrode pads, and such that parts of the starter solder material corresponding to the second starter solder portions are disposed on the second electrode pads.
the starter reflow comprises, after contacting, reflowing the starter solder material to form the first starter solder bumps on the first electrode pads, and the second starter solder bumps on the second electrode pads.

10. The method of claim 9, wherein:
the starter solder transfer head comprises:
a base sheet; and
an adhesive layer provided onto the base sheet and adapted to hold the starter solder material thereon; and
attaching the starter solder material comprises adhering the starter solder material onto the adhesive layer.

11. The method of claim 10, wherein the starter solder material comprises solder powder, and wherein attaching the starter solder material comprises coating the solder powder onto the adhesive layer.

12. The method of claim 2, further comprising, prior to providing the first starter solder portions and the second starter solder portions, adding flux to the first and second electrode pads.

13. The method of claim 6, further comprising selecting respective amounts of the first solder portions and the second solder portions such that the first final solder bumps have substantially identical heights with respect to the second final solder bumps.

14. The method of claim 1, wherein at least one of the starter reflow and the filler reflow comprises thermal compression bonding.

15. The method of claim 1, further comprising cleaning the substrate of any flux residue after at least one of the starter reflow and the filler reflow.

16. The method of claim 2, wherein disposing respective filler solder portions comprises:
attaching the filler solder portions onto a filler solder transfer head; and
contacting respective ones of the filler solder portions to respective ones of the first starter solder bumps and the second starter solder bumps.

17. The method of claim 16, wherein:
the filler solder transfer head comprises:
a base sheet; and
an adhesive layer provided onto the base sheet and adapted to hold the starter solder material thereon; and
attaching the filler solder portions comprises adhering the filler solder portions onto the adhesive layer.

18. The method of claim 17, wherein:
the filler solder transfer head comprises a stencil layer defining stencil openings therein, the openings exhibiting a pattern corresponding to a pattern of the first electrode pads and the second electrode pads; and
attaching comprises attaching each of the filler solder portions to the adhesive layer through a respective one of the stencil openings

19. The method of claim 17, wherein the filler solder portions comprise solder balls, and wherein attaching the filler solder portions comprises adhering the solder balls to the adhesive layer.

20. The method of claim 17, further comprising, prior to attaching the filler solder portions, coating flux onto the adhesive layer.

21. The method of claim 2, wherein the substrate comprises a solder resist layer thereon, the solder resist layer defining first solder resist openings therethrough placed in registration with the first electrode pads, and second solder resist openings therethrough placed in registration with the second electrode pads, the second solder resist openings being larger than the first solder resist openings.
